(19) United States
(12) Patent Application Publication
(10) Pub. No.: US 2025/0351500 A1
(43) Pub. Date: Nov. 13, 2025

(54) STRAIN-RELAXED PSEUDO-SUBSTRATES AND METHODS OF MAKING SAME USING THERMAL POROSIFICATION

(71) Applicant: Wisconsin Alumni Research Foundation, Madison, WI (US)

(72) Inventors: Swarnav Mukhopadhyay, Madison, WI (US); Shubhra S. Pasayat, Middleton, WI (US); Chirag Gupta, Middleton, WI (US); Surjava Sanyal, Madison, WI (US)

(21) Appl. No.: 18/657,155

(22) Filed: May 7, 2024

(51) Int. Cl. H01L 29/205; H01L 21/02; H01L 29/20

(52) U.S. Cl. CPC H10D 62/824; H01L 21/02458; H01L 21/0254; H10D 62/8503

(57) ABSTRACT

Pseudo-substrates for the growth of metal nitride alloys are provided. The alloys are incorporated into heterostructures that include at least one porosified layer, a planarizing coalescence layer on the at least one porosified layer, and a terminal layer that includes or consists of a layer of at-least-partially strain-relaxed, non-porous metal nitride alloy. The pseudo-substrates are grown epitaxially and porosified via thermal decomposition in situ without the need for a decomposition stop layer.

### REFERENCE TO GOVERNMENT RIGHTS

This invention was made with government support under N00014-22-1-2267 awarded by the NAVY/ONR. The government has certain rights in the invention.

### BACKGROUND

N-polar GaN-based high electron mobility transistors (HEMTs) hold promise as a viable option for high-frequency operation within the millimeter-wave spectrum and have demonstrated outstanding performances in both small and large signal operations. (Li, Weiyi, et al., IEEE Transactions on Electron Devices 70, no. 4 (April 2023): 2075-80; Romanczyk, Brian, et al., IEEE Transactions on Electron Devices 65, no. 1 (January 2018): 45-50; Wienecke, Steven, et al., IEEE Electron Device Letters 38, no. 3 (March 2017): 359-62; Zheng, Xun et al., In 2017 75th Annual Device Research Conference (DRC), 1-2. South Bend, IN, USA: IEEE, 2017; Denninghoff, Daniel J. et al., IEEE Electron Device Letters 33, no. 6 (June 2012): 785-87; Denninghoff, D., J. et al., In 71st Device Research Conference, 197-98. Notre Dame, IN, USA: IEEE, 2013.) However, even after extreme scaling of the vertical and lateral dimensions of the HEMTs, the performance of the GaN channel HEMTs is limited by the optical phonon scattering. (Fang, Tian et al., IEEE Electron Device Letters 33, no. 5 (May 2012): 709-11.) To further improve the performance of HEMTs, the use of an InGaN channel would be beneficial over a GaN channel, due to the lower effective mass and higher saturation velocity of electrons in InGaN. (Zhang, Yachao, et al., Applied Physics Letters 115, no. 7 (Aug. 13, 2019): 072105.) Recently, In_{0.05}Ga_{0.95}N channel Ga-polar GaN HEMTs deposited using the metal-organic chemical vapor deposition (MOCVD) technique have shown very high two-dimensional electron gas (2DEG) mobility of 1681 cm²/V·s with a 2DEG sheet carrier density (ns) of 1.3×10¹³/cm³. (Zhang, Yachao, et al., Applied Physics Express 9, no. 6 (May 23, 2016): 061003.) Also, the optical phonon scattering was determined to be lower in InGaN channel HEMTs compared to the GaN channel HEMTs, which is suitable for high-temperature operation. (Zhang, Yachao, et al., Applied Physics Express 11, no. 9 (Jul. 31, 2018): 094101.) However, as the deposited InGaN channel on top of the GaN buffer is fully strained to GaN, the advantage of the lower effective mass of the InGaN will not be realized. Li et. al have demonstrated a 70% strain-relaxed InGaN channel Ga-polar HEMT deposited on a porous GaN pseudo-substrate with a 10% improvement of the on-resistance. (Li, Weiyi, et al., Semiconductor Science and Technology 35, no. 7 (June 2020): 075007.)

The porosification of Ga-polar and N-polar GaN buffer layers in a pseudo-substrate can be achieved using electrochemical etching or thermal-decomposition techniques. (Pasayat, Shubhra S., et al., Semiconductor Science and Technology 34, no. 11 (October 2019): 115020; Pasayat, Shubhra S. et al., Materials 13, no. 1 (January 2020): 213; Chan, Philip, et al., Applied Physics Letters 119, no. 13 (Sep. 28, 2021): 131106; Collins, Henry, et al., Applied Physics Letters 119, no. 4 (Jul. 26, 2021): 042105.) Electrochemical etching requires complex processing steps, such as mesa isolation, and electrochemical etching of highly n-type doped GaN buffer layers, which are not suitable for HEMT processing, as the highly n-type doped layer can cause microwave losses during high frequency operation. (Pasayat, Shubhra S., et al., 2019; Pasayat, Shubhra S., et al., 2020.) Also, the relaxation is dependent on the size of the mesa, which can cause in-plane variation in ns, introducing reliability issues.

The thermal decomposition technique is more suitable for large-area porosification and minimizing processing steps. (Li, Weiyi, et al., 2020; Chan, Philip, et al., 2021.) This process relies on the decomposition of a high-indium-composition InGaN decomposition layer (DL) underneath a GaN decomposition stop layer (DSL), deposited at an elevated temperature. (Chan, Philip, et al., 2021.) Primarily, this method applies to Ga-polar InGaN/GaN epitaxial structures, where the departure of nitrogen through v-pits (formed due to lattice mismatch between InGaN and GaN) results in metallic indium segregation and formation of voids. (Stránská Matějová, Jana, et al., Journal of Applied Crystallography 54, no. 1 (Feb. 1, 2021): 62-71; Smalc-Koziorowska, Julita, et al., ACS Applied Materials & Interfaces, Feb. 2, 2021.) However, in N-polar InGaN, the v-pit formation is not present; rather, the lattice mismatch between InGaN and GaN layer results in hillock formation. (Keller, Stacia, et al., Semiconductor Science and Technology 29, no. 11 (Nov. 1, 2014): 113001.) Due to the absence of the v-pits, the porosification of the N-polar InGaN DL is not possible without damaging the GaN DSL layer following the method described by Chan et. al. (Chan, Philip, et al., 2021.) Therefore, the nitrogen cannot escape from the InGaN layer and, thus, it is not straightforward to achieve porous InGaN films. Also, the extremely high indium content in the DL can degrade the material quality and generate a high density of hillocks, which cannot be mitigated in subsequent depositions of InGaN pseudo-substrate above the InGaN DL.

### SUMMARY

Pseudo-substrates for the growth of metal nitride alloys are provided. Method of fabricating the pseudo-substrates and devices incorporating the pseudo-substrates are also provided.

One embodiment of a pseudo-substrate includes: a template and a pseudo-substrate heterostructure on the template. The pseudo-substrate heterostructure includes: a first porosified layer comprising a metal nitride alloy on a template; a first coalescence layer comprising a metal nitride alloy on the first porosified layer; optionally, one or more additional structures on the first coalescence layer, wherein each of the one or more additional structures comprises an additional porosified layer comprising a metal nitride alloy; and an additional coalescence layer comprising a metal nitride alloy on the additional porosified layer; and an upper, non-porosified, at-least-partially strain-relaxed layer comprising a metal nitride alloy on the first coalescence layer or on a terminal additional coalescence layer.

Electronic or optoelectronic device incorporating the pseudo-substrates include one or more epitaxial active layers on a pseudo-substrate. Such devices include high electron mobility transistors, light-emitting diodes, and laser diodes.

One embodiment of a method of making a pseudo-substrate includes the steps of: forming a first layer comprising a metal nitride alloy on a template using epitaxial growth; porosifying the metal nitride alloy of the first layer via a thermal decomposition of the metal nitride alloy to form a first porosified layer; forming a first coalescence layer comprising a metal nitride alloy on the first porosified layer via epitaxial growth; optionally, forming one or more additional structures on the first coalescence layer, wherein each of the one or more additional structures are made by: forming an additional layer comprising a metal nitride alloy and porosifying the additional layer via a thermal decomposition of the metal nitride alloy to form an additional porosified layer; and forming an additional coalescence layer comprising a metal nitride alloy on the additional porosified layer via epitaxial growth; and forming an upper, non-porosified, at-least-partially strain-relaxed layer comprising a metal nitride alloy on the first coalescence layer or on a terminal additional coalescence layer.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings.

FIG. 1 shows the epitaxial structure of an InGaN pseudo-substrate grown on N-polar GaN via multi-step porosification during MOCVD growth.

FIGS. 2A-2C show (FIG. 2A) reciprocal space mapping (RSM) of the structure S₀ (see FIG. 1) across the (1̅1̅24) GaN reflection showing peaks corresponding to almost fully strained InGaN, (FIG. 2B) an omega-2theta scan of structure S₀ across the (0002) GaN reflection, and (FIG. 2C) a top view scanning electron microscopy (SEM) image of the epitaxial structure for InGaN/InGaN/GaN SL_{A} grown on N-polar GaN (structure S₀).

FIGS. 3A-3B show top view SEM images of (FIG. 3A) structure S₀ after in situ porosification and (FIG. 3B) structure S₁ after the deposition of a GaN coalescence layer.

FIGS. 4A-4B show (FIG. 4A) an SEM image of the surface of structure S₂ and (FIG. 4B) RSM of structure S₂ across the (1̅1̅24) GaN reflection showing 10% strain relaxation.

FIGS. 5A-5C show (FIG. 5A) RSM of structure S₄ across the (1̅1̅24) GaN reflection showing 40% strain relaxation, (FIG. 5B) a top view SEM image of structure S₄ indicating a smooth surface, and (FIG. 5C) a cross-sectional SEM of structure S₄ showing in-situ porous underlayers (SL_{A} & SL_{B1}), along with the top SL_{B2} layers that were not porosified after a thermal anneal.

FIGS. 6A-6B show AFM images (5 μm×5 μm) of (FIG. 6A) structure S₀ and (FIG. 6B) structure S₄.

FIGS. 7A-7B show (FIG. 7A) RSM of comparative structure S₅ across the (1̅1̅24) GaN reflection showing only 8.5% strain relaxation and (FIG. 7B) top-view SEM image of the surface of comparative structure S₅.

FIGS. 8A-8B show (FIG. 8A) a comparison of the photoluminescence (PL) spectra of structures S₄ and S₅ and (FIG. 8B) the relation between PL emission wavelength, indium composition, and strain relaxation.

FIG. 9 shows variation of hillock density for different pseudo-substrate samples.

FIG. 10 is a schematic diagram of one embodiment of a HEMT.

FIG. 11 is a schematic diagram of one embodiment of an LED.

### DETAILED DESCRIPTION

Pseudo-substrates for the growth of metal nitride alloys are provided. Method of fabricating the pseudo-substrates are also provided. Pseudo-substrates made using the methods can be used as high-quality growth substrates for a variety of electronic and optoelectronic devices, including high-mobility electron transistors (HEMTs) and light-emitting devices, such as light-emitting diodes (LEDs) and laser diodes (LDs).

The pseudo-substrates are heterostructures composed of stacked layers of metal nitride alloys. The metal nitride alloys may be, but are not limited to, binary, ternary, and higher order group III-nitrides. In some embodiments, the group III-nitrides of the pseudo-substrates and the group III-nitride overlayers that are deposited thereon are indium- and aluminum-containing gallium nitrides. However, other group III-nitrides, including transition metal group III-nitrides, such as scandium group III-nitrides and yttrium group III-nitrides, as well as boron group III-nitrides, can also be used. The metal nitride alloys may be p-type doped, n-type doped, or undoped/unintentionally doped and the dopant type and concentration can be different in different layers of the heterostructures. Illustrative dopants include magnesium, silicon, carbon, and oxygen atoms.

The indium- and aluminum-containing group III-nitride alloys, in those pseudo-substrates that contain such alloys, include InGaN, AlGaN, and AlInGaN alloys, and all of these can be represented by the general formula AlₐIn_{b}Ga_{(1-a-b)}N. For conciseness, the term “(Al,In)GaN” is used hereinafter to refer to these AlₐIn_{b}Ga_{(1-a-b)}N alloys.

The pseudo-substrates are characterized by a layer of porosified metal nitride alloy having a planarizing coalescence layer on its porous upper surface. The porosified layer is more strain-relaxed and compliant and adopts a larger in-plane lattice constant that its non-porosified counterpart, while the coalescence layer improves the surface morphology (lowers RMS roughness). Together with the porosified layer, the coalescence layer acts to reduce hillock density at the terminating surface of the pseudo-substrate. The overall result is a pseudo-substrate having a high degree of strain relaxation and a smooth, high-crystal-quality surface on which metal nitride-based devices can be formed.

Notably, the porosification can be carried out via thermal decomposition in situ and can be carried out in the absence of a decomposition stop layer. Therefore, the porosification can be conducted before any additional material layers are deposited on the layer to be porosified. The pseudo-substrate heterostructures may contain a single porosified metal nitride alloy layer, along with its overlying coalescence layer, or may contain multiple, vertically stacked porosified metal nitride alloy layers, each with a corresponding overlying coalescence layer. If multiple stacked porosified metal nitride alloy layers and metal nitride alloy coalescence layers are present in the structure, the metal nitride alloys in the porosified layers and the coalescence layers may the same or different.

Porosification is carried out by subjecting a metal nitride alloy a high-temperature thermal treatment to produce a porosified layer. During the high-temperature porosification process, the metal nitride alloy decomposes to form metallic and/or metal-rich phases and N_{2(g)}, leaving pores in the thermally treated metal nitride alloy layers. The resulting porosified layer contains a high density of small pores and, therefore, has a lower stiffness relative to the non-porous layer from which it is made. As a result, the porosified metal nitride layer is more strain-relaxed and compliant and adopts a larger in-plane lattice constant. The temperature of the thermal treatment should be sufficiently high to induce the decomposition of the alloy to partially relax the heterostructure and should be carried out for a time sufficient to achieve a desired degree of porosification. By way of illustration, temperatures in the range from 900° C. to 1500° C. and times in the range from 5 to 60 min can be used to porosify metal nitride alloys. However, the methods described herein are not limited to porosification temperatures and times in these ranges.

The at least one porosified layer includes or consists of a porosified metal nitride alloy. The porosified layer may be a single layer of metal nitride alloy or may be a superlattice (SL) that includes two or more metal nitride alloy sublayers separated by sublayers of a different nitride alloy. The superlattices in the pseudo-substrate heterostructures are periodic structures composed of repeating stacked thin sublayers of nitride alloy separated by thin sublayers of a different nitride alloy. Each repeating unit of sublayers defines one “period” in a superlattice and a superlattice has at least two periods, but may include more. For example, a SL may have between 2 and 50 periods, including embodiments in which the SLs include between 5 and 30 periods. Typically, each of the sublayers in a SL has a thickness of no greater than 15 nm. For example, sublayer thicknesses in the range from 5 nm to 10 nm may be used. However, thicknesses outside of these ranges can be used.

It is not necessary that a metal nitride alloy layer be porosified throughout its entire thickness. It is sufficient that the depth of the porosification provides the desired degree of strain relaxation in the structure. Thus, a porosified layer, including a porosified superlattice, may be porosified through only a portion of its depth. By way of illustration, a porosified layer may be porosified through only 40%, 50%, 60%, 70%, 80%, or 90% of its depth.

The porosification of a layer results in the formation of holes in the layer surface. To fill these holes and provide a smoother surface, a coalescence layer of metal nitride alloy is grown over the porosified layer. The coalescence layer should be sufficiently thick to fill most or all the holes in the upper surface of the porosified layer and provide a continuous planarizing layer. However, it is desirably not so thick that it does not maintain the lattice constant of the layer upon which it is grown. Typically, a coalescence layer thickness of no greater than 50 nm is sufficient. By way of illustration only, coalescence layers having a thickness in the range from 20 nm to 50 nm may be used.

When multiple porosified layers and their overlying coalescence layers are incorporated into the heterostructure, the fabrication of the pseudo-substrate is carried out using a multi-step porosification process in which thermal porosification takes place after each layer to be porosified is deposited, followed by the deposition of a coalescence layer. A single porosified layer may provide the pseudo-substrate with the necessary degree of strain relaxation and lattice constant expansion for a particular application. However, if a higher degree of strain relaxation is desired, the number of porosified layers can be increased to further relax the heterostructure. In some embodiments of the pseudo-structures, the first porosified layer is more porous and has a higher degree of strain relaxation than the overlying porosified layers.

Group III-nitrides that can be used in the coalescence layers and the sublayers of a superlattice include, but are not limited to GaN, AlN, AlInGaN, AlInN, AlBN, GaBN alloy and AlScN alloys. The group III-nitrides of the coalescence layers and the sublayers can be, but need not be, the same.

Optionally, the pseudo-substrates may include at least one additional porosified layer that includes or consists of porosified metal nitride alloy. Each of the one or more additional overlying porosified layers may be a single layer of a porosified metal nitride alloy or may be a superlattice (SL) that includes two or more porosified metal nitride alloy sublayers separated by sublayers of a different metal nitride alloy.

Finally, the pseudo-substrate includes a terminal layer that includes or consists of a layer of at-least-partially strain-relaxed metal nitride alloy which may be a single layer of a non-porous meal nitride alloy or may be a superlattice (SL) that includes two or more non-porous metal nitride alloy sublayers separated by sublayers of a different non-porous metal nitride alloy.

The strain-relaxed pseudo-substrates are grown with high crystal quality, as reflected in their low RMS surface roughness. Using the single or multi-step porosification methods described herein, pseudo-substrates having an upper surface with an RMS surface roughness of 5 nm or lower, 3 nm or lower, and 2 nm or lower, as measured by atomic force microscopy over an area of 1 μm×1 μm, or larger, can be grown. By way of illustration, pseudo-substrates having an upper surface roughness in the range from 1 nm to 5 nm can be grown.

The pseudo-substrate heterostructures can be grown epitaxially using a variety of physical or chemical vapor deposition techniques, including MOCVD, molecular beam epitaxy (MBE), and plasma enhanced chemical vapor deposition (PECVD). Epitaxial growth with a single-step or multi-step porosification process and be carried out in situ in the deposition reactor.

By way of illustration, in MOCVD epitaxial growth is carried out by exposing the growth template or a previously grown layer of the heterostructure to vapor comprising metal-containing (e.g., indium-containing, gallium-containing, aluminum-containing, scandium-containing, and/or yttrium-containing) and nitrogen-containing precursor metal-organic compounds that decompose and react on the surface to form the various layers of the heterostructure. These precursors may be introduced into the vacuum chamber of an MOCVD reactor with a carrier gas, such as hydrogen (H₂) and/or nitrogen (N₂). Examples of metal-organic compounds that may be used as precursors include, but are not limited to, trimethyl gallium (TMGa), triethyl gallium (TEGa), trimethyl aluminum (TMAl), triethyl aluminum (TEAl), trimethyl indium (TMI), and triethyl indium (TEI). Other known precursor compounds can be used depending on the nitride alloy being deposited. Ammonia (NH₃) is typically used as a nitrogen precursor molecule.

### Illustrative Example—(Al,In)GaN-Based Pseudo-Substrates with One or More Porosified Layers

One, non-limiting, example of a pseudo-substrate is a heterostructure that incorporates a first porosified layer that includes or consists of porosified (Al,In)GaN. The first porosified layer (referred to herein as L_{A}) may be a single layer of porosified (Al,In)GaN or may be a superlattice (SL) that includes two or more porosified (Al,In)GaN sublayers separated by sublayers of a different group III-nitride. If L_{A} is an SL, it is referred to herein as SL_{A}.

This exemplary example may, optionally, include at least one overlying porosified layer (L_{B1}) that includes or consists of porosified (Al,In)GaN. Each of the one or more overlying porosified layers may be a single layer of porosified (Al,In)GaN or may include two or more porosified (Al,In)GaN sublayers separated by sublayers of a different group III-nitride. If L_{B1} is an SL, it is referred to herein as SL_{B1}.

Finally, this exemplary pseudo-substrate includes a terminal layer (L_{B2}) that includes or consists of a layer of at-least-partially strain-relaxed (Al,In)GaN, which may be a single layer of the (Al,In)GaN or may be a superlattice comprising two or more (Al,In)GaN sublayers. If L_{B2} is a superlattice, it is referred to herein as SL_{B2}.

The indium content, aluminum content, or combined indium and aluminum content in the (Al,In)GaN alloy of L_{A} is higher than the indium content, aluminum content, or combined indium and aluminum content in the (Al, In)GaN alloy of L_{B1}. (For conciseness the term “(In/Al)” is used hereinafter to mean “indium, aluminum, or combined indium and aluminum” in reference to InGaN alloys, AN alloys, and AlInGaN alloys, respectively.) The higher (In/Al) content renders the (Al,In)GaN in L_{A} less thermally stable than the (Al,In)GaN in L_{B1}, which has a lower average (In/Al) content. This difference leads to a higher porosity in L_{A} than in L_{B1} after thermal porosification. The (In/Al) content of L_{B2} is also greater than that of the LA and may be, but is not necessarily, the save as that of L_{B1}. As a result, the incorporation of L_{A} into the pseudo-substrate heterostructure results in a higher degree of strain relaxation and a higher lattice constant in L_{B2}, relative to a pseudo-substrate heterostructure that lacks L_{A}. Because the pseudo-substrates have a higher lattice constant than other known pseudo-substrates and GaN substrates, they are particularly well-suited for use as substrates for the fabrication of longer wavelength light-emitting devices.

The indium and/or aluminum content in the layers of pseudo-substrates can be summarized as follows, where a and b, a′ and b′, and a″ and b″ notation in the subscripts of the chemical formula is used to indicate that the (Al,In)GaN alloy is in L_{A}, L_{B1}, or L_{B2}, respectively. The (Al,In)GaN alloy of L_{A} comprises AlₐIn_{b}Ga_{(1-a-b)}N, where 0≤a≤1 and 0≤b≤1, provided that 0<(a+b) and 0<(1−a−b). The (Al,In)GaN alloy of the one or more LB1 layers comprise Al_{a′}In_{b′}Ga_{(1-a′-b′)}N, where 0≤a′≤1 and 0≤b′≤1, provided that 0<(a′+b′), 0<(1−a′−b′), and (a′+b′)<(a+b). The (Al,In)GaN alloy in LB2 comprises Al_{a″}In_{b″}Ga_{(1-a″-b″)}N, where 0≤a″≤1 and 0≤b″≤1, provided 0<(a″+b″), 0<(1−a″−b″), and (a″+b″)<(a+b).

Coalescence layers between the porosified layers (i.e., between L_{A}s and L_{B1}, between neighboring L_{B1}s, and between L_{B1} and L_{B2}) in the pseudo-substrate heterostructures improve the surface morphology of the pseudo-substrate. Together with the L_{A}, these coalescence layers act to reduce hillock density at the terminating surface of the pseudo-substrate. The overall result is a pseudo-substrate having a high degree of strain relaxation and a smooth, high-crystal-quality surface.

The superlattices in the pseudo-substrate heterostructures are periodic structures composed of repeating stacked thin sublayers of (Al,In)GaN separated by thin sublayers of a different group III-nitride. Each repeating unit of sublayers defines one “period” in a superlattice and a superlattice has at least two periods, but may include more. For example, a SL may have between 2 and 50 periods, including embodiments in which the SLs include between 5 and 30 periods.

Typically, each of the sublayers in a SL has a thickness of no greater than 15 nm. For example, (Al,In)GaN sublayer thicknesses in the range from 5 nm to 10 nm may be used. The GaN or AlN sublayer in each period is typically the thinnest sublayer with a thickness in the range from, for example, 0.5 nm to 3 nm. If a single (Al,In)GaN layer is used, rather than a SL, the thickness of the (Al,In)GaN layer is typically in the range from 10 nm to 120 nm. However, thicknesses outside of these ranges can be used.

In embodiments of the pseudo-substrates that comprise porosified (Al,In)GaN alloys, during MOCVD growth, the (Al,In)GaN layers or sublayers may be stratified into a high-(In/Al)-content (Al,In)GaN stratum and a low-(In/Al)-content (Al,In)GaN stratum due to the selective evaporation of near-surface In and/or Al atoms during growth. The terms “high-(In/Al)-content (Al,In)GaN” and “low-(In/Al)-content (Al,In)GaN” are not intended to indicate any particular (In/Al) content; rather, they are used merely to indicate that the “high-(In/Al)-content (Al,In)GaN” has a higher (In/Al) concentration than the “low-(In/Al)-content (Al,In)GaN”. For L_{A} and L_{B1} in which the (Al,In)GaN layers or sublayers are stratified, the comparison of the relative (In/Al) content in L_{A} and L_{B} is based on a comparison between the (In/Al) concentrations in the high-(In/Al)-content strata.

The stratification of an (Al,In)GaN alloy in a heterostructure layer or sublayer into high-(In/Al)-content (Al,In)GaN and low-(In/Al)-content (Al,In)GaN strata may result from growing an overlying group III-nitride layer in a hydrogen and nitrogen carrier gas, which promotes the selective evaporation of indium and/or aluminum near the upper surface of the previously deposited (Al,In)GaN. In the case of a superlattice, the overlying group III-nitride may be another sublayer of the superlattice, while in the case of a single-layer (Al,In)GaN, the overlying layer may be the coalescence layer. This near-surface indium and/or aluminum evaporation gives rise to the formation of the low-(In/Al)-content (Al,In)GaN stratum. The stratification of the (Al,In)GaN alloy is advantageous because, while the carrier gas reduces the (In/Al) content of the (Al,In)GaN, it also reduces the hillock density at the surface of the layer or sublayer, thereby improving the surface morphology and reducing the RMS surface roughness. The low-(In/Al)-content (Al,In)GaN strata will typically have an (In/Al) concentration that is 1% to 10%, including 2% to 5%, lower than that of the high-In-content (Al,In)GaN strata.

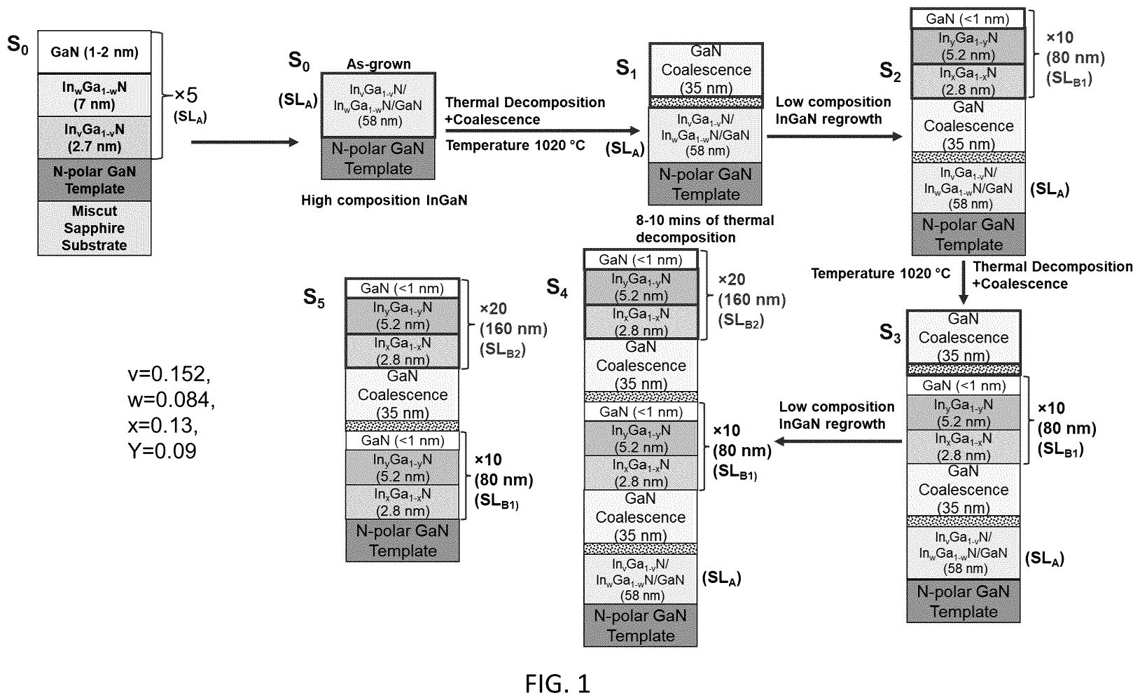

One embodiment of a pseudo-substrate in shown schematically in FIG. 1. In this pseudo-substrate, the L_{A}, L_{B1}, and L_{B2} are InGaN sublayer-containing superlattices (SL_{A}, SL_{B1}, and SL_{B2}). However, in the figures and the following description, one of, more than one of, or all the InGaN sublayer-containing superlattices could be replaced by AlGaN sublayer-containing or AlInGaN sublayer-containing superlattices or with a single layer of InGaN, a single layer of AlGaN, or a single layer of AlInGaN. For illustrative purposes, the pseudo-substrate of FIG. 1 is depicted using various heterostructure layer thicknesses, InGaN alloy compositions, SL periods, and processing temperatures. However, the pseudo-substrates and MOCVD growth methods described herein are not limited to the layer thicknesses, alloy compositions, SL periods, and processing temperatures shown in FIG. 1. Moreover, while the substrate used in the illustrative embodiment of FIG. 1 includes an N-polar GaN template on miscut sapphire, other templates can be used.

The pseudo-substrate heterostructure is grown on a template having a lattice constant that is sufficiently close to the lattice constant of the (Al,In)GaN alloy to allow for epitaxial growth. GaN is an example of a suitable template material. The GaN may be Ga-polar or N-polar GaN. Because InGaN can generally be grown with a higher indium content on N-polar GaN, N-polar GaN may be preferred for InGaN-containing L_{A} layers. The GaN template may itself be supported on a growth substrate, such as a sapphire substrate. In some embodiments, the template is N-polar GaN grown on sapphire miscut (for example, 4° miscut) to the a-plane. The use of miscut sapphire is advantageous because it provides miscut steps in N-polar GaN that promote step-flow deposition during MOCVD growth. This reduces hexagonal hillock formation on the surface for a smoother surface morphology and reduces dislocation defect density.

The indium content in the InGaN alloys of L_{A} will depend upon the template being used and the chosen epitaxial growth conditions. The InGaN sublayers of SL_{A} in the pseudo-substrate of FIG. 1 are stratified into a high-In-content InGaN alloy represented by the formula InᵥGa₁₋ᵥN and a low-In-content InGaN alloy represented by the formula In_{w}Ga_{1-w}N, where w<v. This stratification occurs when L_{A} is grown on the template via MOCVD. The high-In-content and low-In-content InGaN stratum of L_{A} include, but are not limited to, alloys having an indium content in the range from 1% to 30%. However, it is preferable for the InᵥGa₁₋ᵥN alloy of L_{A} to have an indium content of at least 10% (i.e., v≥0.1) to promote porosification via heat treatment at wafer temperatures<1100° C. By way of illustration only InᵥGa₁₋ᵥN, where 0.01≤v≤0.3, including 0.05≤v≤0.2 and further including 0.1≤v≤0.2, may be used.

In the pseudo-substrate of FIG. 1, the InGaN of SL_{A} and SL_{B1} are stratified. SL_{A} has 5 periods, each of which includes a high-In-content stratum of In_{0.152}Ga_{0.848}N, an overlying low-In-content stratum of In_{0.084}Ga_{0.96}N, and a GaN sublayer. Each such period is referred to as a “InGaN/InGaN/GaN’ period. For simplicity, in the remaining panels of FIG. 1, SL_{A} is depicted as a single layer (“InGaN/InGaN/GaN 58 nm”). The SL_{A} sublayers are grown as strained layers and are desirably thin to eliminate or minimize the defect density within the SL and maintain a smooth surface.

Once formed, the (Al,In)GaN alloys in the L_{A} are subjected to a high-temperature thermal anneal to produce a porosified L_{A}. During the high-temperature porosification process, the (Al,In)GaN decomposes to form metallic In and/or metallic Al, N_{2(g)}, and a Ga-rich material, leaving pores in the alloy layers and sublayers. The resulting porosified L_{A} contains a large density of small pores and, therefore, has a lower stiffness relative to the non-porous L_{A}. As a result, the porosified L_{A} is more strain-relaxed and compliant and adopts a larger in-plane lattice constant. The temperature of the thermal anneal should be sufficiently high to induce the decomposition of the (Al,In)GaN to partially relax the heterostructure and should be carried out for a time sufficient to achieve a desired degree of porosification. By way of illustration, temperatures in the range from 900° C. to 1200° C. and times in the range from 5 to 30 min can be used to porosify InGaN alloys and temperatures in the range from 1200° C. to 1500° C. can be used to porosify AlGaN and AlInGaN alloys. However, the methods described herein are not limited to annealing temperatures and times in these ranges.

It is not necessary that L_{A} be porosified throughout its entire thickness. It is sufficient that the depth of the porosification provides the desired degree of strain relaxation in the structure. Thus, an L_{A}, including an SL_{A}, may be porosified through only a portion of its depth. By way of illustration, an L_{A} may be porosified through only 40%, 50%, 60%, 70%, 80%, or 90% of its depth.

The thickness of a single-layer L_{A} or the number of periods in an SL_{A} and/or the thickness of the (Al,In)GaN sublayers in each period may be selected to achieve a desired degree of strain relaxation upon porosification. Generally, a thicker layer and/or a SL having more periods will increase the porosification and strain-relaxation. However, there may be a tradeoff between a higher degree of strain relaxation and a lower crystal quality and surface morphology.

The porosification of the L_{A} results in the formation of holes in the layer surface. To fill these holes and provide a smoother surface, a layer of group III-nitride is grown over the porosified L_{A}. This layer is referred to as a “coalescence layer.” Like SL_{A}, the coalescence layer may be grown using MOCVD or other epitaxial growth technique. The coalescence layer should be sufficiently thick to fill most or all the holes in the upper surface of the porosified L_{A} and provide a continuous planarizing layer. However, it is desirably not so thick that it reverts to its unstrained group III-nitride lattice constant, rather than maintaining the lattice constant of the SL_{A} upon which it is grown. Typically, a coalescence layer thickness of no greater than 50 nm is sufficient. By way of illustration only, coalescence layers having a thickness in the range from 20 nm to 50 nm may be used.

If ore than one strain-relaxing porosified layer is desired, the growth of the pseudo-substrate heterostructure is then continued with the growth of an intermediate structure on the GaN coalescence layer. This intermediate structure includes at least one additional porosified and partially strain relaxed L_{B1}, which may be a single layer or a superlattice. (For clarity, in embodiments that include more than one porosified L_{B1} in the intermediate structure, the L_{B1} layers in the series would be designated L_{B1i}, L_{B1ii}, L_{B1iii}, etc.) In the illustrative embodiment shown in FIG. 1, L_{B1} is a superlattice, SL_{B1}, which is composed of 10 stacked periods. The InGaN in each period is stratified into a high-In-content InGaN stratum and a low-In-content InGaN stratum as a result of the overgrowth of a GaN sublayer in each period. Here again, the designations “high-In-content InGaN” and “low-In-content InGaN” are used only to indicate that the latter InGaN alloy has a lower indium concentration than the former. The high-In-content InGaN in SL_{B1} can be represented by the formula InₓGa₁₋ₓN and the low-In-content InGaN in SL_{B1} can be represented by the formula In_{y}Ga_{1-y}N, where y<x and x<v. By way of illustration, the indium content in InₓGa₁₋ₓN may be at least 1%, at least 2%, or at least 3% lower than the indium content in InᵥGa₁₋ᵥN. As a result of the lower indium concentration in SL_{B1} relative to SL_{A}, SL_{B1} has a lower porosity than SL_{A} after the multi-step thermal porosification of the of pseudo-substrate heterostructure. However, the porosified SL_{B1} also has a higher degree of strain relaxation than SL_{A}.

As in SL_{A}, the stratification of the InGaN in each period of an SL_{B1} superlattice into a high-In-content InGaN and a low-In-content InGaN is the result of growing the GaN layer of each period in a hydrogen and nitrogen carrier gas during epitaxial growth, which promotes the evaporation of indium from the upper stratum of the previously deposited InGaN and reduces the RMS surface roughness of the heterostructure.

The indium content in the InGaN alloys of SL_{B1} will depend upon the chosen MOCVD conditions. The high-In-content and low-In-content InGaN of SL_{B1} include, but are not limited to, alloys having an indium content in the range from 1% to 30%. However, it is preferable for the InₓGa₁₋ₓN alloy of SL_{B1} to have an indium content of at least 10% (i.e., a≥0.1) to promote porosification via heat treatment. By way of illustration only, InₓGa₁₋ₓN, where 0.1≤x≤0.2 may be used. In_{y}Ga_{1-y}N will typically have an indium concentration that is 1% to 10% lower than that of InₓGa₁₋ₓN and InₓGa₁₋ₓN will typically have an indium concentration that is 1% to 5% lower than that of InᵥGa₁₋ᵥN.

An SL_{B1} will include at least two periods, but may include more. Typically, SL_{B1} will have 20 or fewer periods. However, a higher number of periods can be used. An SL_{B1} composed of at least 5 periods, at least 10 periods, at least 15 periods, or a greater number may be employed. In some embodiments of the pseudo-substrates, SL_{B1} has from 5 to 20 periods. The SL_{B1} sublayers are desirably thin to eliminate or minimize the defect density within the SL and maintain a smooth surface. Typically, each of the InGaN sublayers in an SL_{B1} has a thickness of no greater than 15 nm. For example, InGaN layer thicknesses in the range from 1 nm to 10 nm may be used. The GaN layer in each period is typically the thinnest layer with a layer thickness in the range from, for example, 0.5 nm to 3 nm.

Once formed, each SL_{B1} is porosified using a high-temperature anneal as described previously. As a result of this multi-step, in situ porosification, the SL_{B1} is strain relaxed to a higher degree than SL_{A} and, as a result, is more compliant and has a larger in-plane lattice constant. The SL_{B1} need not be porosified throughout its entire depth; it is sufficient that the depth of the porosification provides the desired degree of strain relaxation in the structure. Thus, SL_{B1} may be porosified through only a portion of its depth. By way of illustration, SL_{B1} may be porosified through only 40%, 50%, 60%, 70%, 80%, or 90% of its depth.

The number of periods in an SL_{B1} and/or the thickness of the (Al,In)GaN alloy in each period may be selected to achieve a desired degree of strain relaxation upon porosification. Generally, a thicker SL_{B1} having more periods will increase the porosification and strain-relaxation. However, there may be a tradeoff between a higher degree of strain relaxation and a lower crystal quality and surface morphology.

Each of the one or more SL_{B1} superlattices in the intermediate structure has a corresponding coalescence layer, such that in embodiments of the pseudo-substrates having two or more porosified SL_{B1}s in the intermediate structure, the SL_{B1}s are vertically stacked and separated by the coalescence layers. The panels designated “SY” and “S₃” in FIG. 1 show a growing pseudo-substrate with an SL_{B1} before porosification and after porosification and coalescence, respectively. Like the coalescence layer on SL_{A}, the coalescence layer on each SL_{B1} is desirably sufficiently thin to retain the lattice constant of the SL_{B1} upon which it is grown. Typically, a coalescence layer thickness of 50 nm or lower is sufficient. By way of illustration only, coalescence layers having a thickness in the range from 20 nm to 50 nm may be used.

After the intermediate structure is grown, an upper (terminal) (Al,In)GaN single layer (L_{B2}) or (Al,In)GaN SL (SL_{B2}) is deposited over the terminal coalescence layer in the intermediate structure. In the illustrative embodiment shown in FIG. 1, SL_{B2} is composed 20 stacked periods, and the InGaN in each period is stratified into a high-In-content InGaN stratum and a low-In-content InGaN stratum and the InGaN sublayers are separated by GaN sublayers. Thus, the layer structure of SL_{B2} is like the layer structure of SL_{B1}, except SL_{B2} does not undergo porosification and coalescence. In addition, the degree of strain relaxation in non-porous SL_{B2} is higher than that of SL_{B1}. The high-In-content InGaN sublayer in the SL_{B2} can be represented by the formula In_{x′}Ga_{1-x′}N and the low-In-content InGaN alloy in an SL_{B2} can be represented by the formula In_{y′}Ga_{1-y′}N, where y′<x′ and x′<v. It is not necessary that the InGaN alloy composition in L_{B2} be the same as the InGaN alloy composition of L_{B1}.

The indium and/or aluminum content of the (Al,In)GaN alloys of an SL_{B2} will depend upon the chosen epitaxial growth conditions. Using InGaN as a representative (Al,In)GaN alloy for an SL_{B2}, the high-In-content and low-In-content InGaN strata of SL_{B2} include, but are not limited to, alloys having an indium content in the range from 1% to 30%. By way of illustration only, In_{x′}Ga_{1-x′}N, where 0.1≤x′≤0.2 may be used. In_{y′}Ga_{1-y′}N will typically have an indium concentration that is 1% to 10% lower than that of In_{x′}Ga_{1-x′}N and In_{x′}Ga_{1-x′}N will typically have an indium concentration that is 1% to 5% lower than that of InᵥGa₁₋ᵥN.

In some embodiments, L_{B2} is the thickest layer in the pseudo-substrate heterostructure. Or, if the layers are SLs, SL_{B2} is the thickest superlattice with the most periods in the pseudo-substrate heterostructure. Typically, SL_{B2} will have 30 or fewer periods. However, a higher number of periods can be used. An SL_{B2} composed of at least 10 periods, at least 15 periods, at least 20 periods, or a greater number may be employed. In some embodiments of the pseudo-substrates, SL_{B2} has from 10 to 30 periods. The SL_{B2} sublayers are desirably thin to eliminate or minimize the defect density within the SL and maintain a smooth surface. Typically, each of the (Al,In)GaN sublayers in an SL_{B2} has a thickness of no greater than 15 nm. For example, InGaN sublayer thicknesses in the range from 1 nm to 10 nm may be used. The GaN sublayer in each period is typically the thinnest sublayer with a thickness in the range from, for example, 0.5 nm to 3 nm.

The L_{B2} of the pseudo-substrate heterostructure is grown with a high degree of strain relaxation. The strain relaxation in an L_{B2} may be measured as a bulk strain relaxation or as the surface or near-surface strain relaxation, since the relaxation gradually increases through the epi-layers up to the upper surface of the L_{B2}. Using the multi-step porosification methods described herein, pseudo-substrates having an L_{B2} with a bulk strain relaxation of at least 20%, at least 30%, and at least 40% can be grown. This includes, but is not limited to, pseudo-substrates having an L_{B2} superlattice with a bulk strain relaxation in the range from 20% to 50%. This high degree of bulk strain relaxation is substantially higher than that achieved using the same pseudo-substrate heterostructure, but without the porosified L_{A} layer. For example, the incorporation of the porosified L_{A} into an otherwise identical pseudo-substrate heterostructure can more than double and even more than triple the bulk and/or surface strain relaxation in the L_{B2} layer.

The composition of the epitaxial layers and the bulk strain relaxation in L_{B2} can be measured using reciprocal space mapping and omega-2theta scans in high-resolution X-ray diffraction, as illustrated in the Example. In terms of surface or near surface relaxation, the multi-step porosification methods described herein can produce pseudo-substrates having a surface strain relaxation for the L_{B2} of at least 60%, at least 70%, and at least 80%. This includes, but is not limited to, pseudo-substrates having a surface or near-surface strain relaxation in the range from 60% to 90%. The surface and near-surface strain relation can be measured using photoluminescence measurements, as illustrated in the Example. The increased strain relaxation in the pseudo-substrates, relative to a pseudo-substrate that is grown without a multi-step porosification, reflects a higher lattice constant and enables the subsequent growth of (Al,In)GaN overlayers with a higher indium and/or aluminum content.

### Devices Incorporating Pseudo-Substrates.

Once formed, the pseudo-substrates can be used as growth substrates for the overgrowth of nitride alloys that benefit from the expanded lattice constant in the terminal layer of the pseudo-substrate heterostructures. This expanded lattice constant enables the growth a nitride alloys having a higher concentration of one or more metal atoms that would otherwise be possible. For example, (Al,In)GaN buffer layers having a higher In and/or Al content can be grown. The higher In and/or Al content (Al,In)GaN alloys are useful in a variety of electronic and optoelectronic devices.

### High Electron Mobility Transistors.

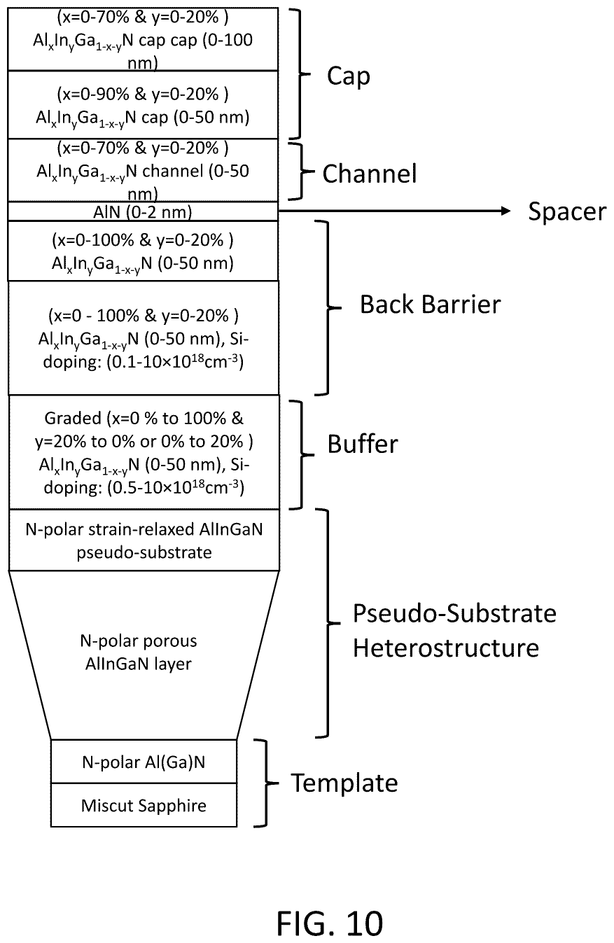

(Al,In)GaN-channel HEMTs are examples of electronic devices that can incorporate the pseudo-substrates. One example of a HEMT is shown in FIG. 10. The group III-nitrides shown in the figure and the layer thicknesses are for illustrative purposes only. Other group III-nitrides and layer thicknesses can be used. The HEMT includes a template, such as N-polar GaN on miscut sapphire, on which a pseudo-substrate heterostructure of a type described herein is fabricated. A buffer layer comprising a graded and, optionally, p-type doped, group III-nitride is grown on L_{B2} of the pseudo substrate and a back barrier is grown on the buffer layer. The back barrier comprises a group III-nitride and comprise a lower sublayer the is n-type doped and an unintentionally doped upper sublayer. A spacer, an (Al,In)GaN-channel layer, and a cap layer over the barrier complete the HEMT heterostructure. The cap may comprise a lower sublayer and an upper sublayer, as shown in the figure.

### Light-Emitting Devices.

The pseudo-substrates described herein can be used to fabricate light-emitting diodes (LEDs) and laser diodes (LDs).

In the light-emitting devices, carriers (electrons and holes) are injected into an active region comprising multiple quantum wells (MQWs) under the influence of an electric field applied across the device heterostructure. In the active region, the carriers recombine to emit photons. In addition to the active region, the devices include two or more electrically conductive contacts positioned to apply the electric field across the heterostructure, including across the MQWs in the active region, and a voltage source coupled to the electrically conductive contacts to apply a voltage difference between the contacts, thereby generating the electric field. Electrically conductive contacts that are positioned to apply an electric field across the active region when the light-emitting device is in operation are referred to as being in electrical communication with the active region. However, the electrically conductive contacts need not be in direct physical contact with the active region; they may be separated from the active region by one or more additional device layers.

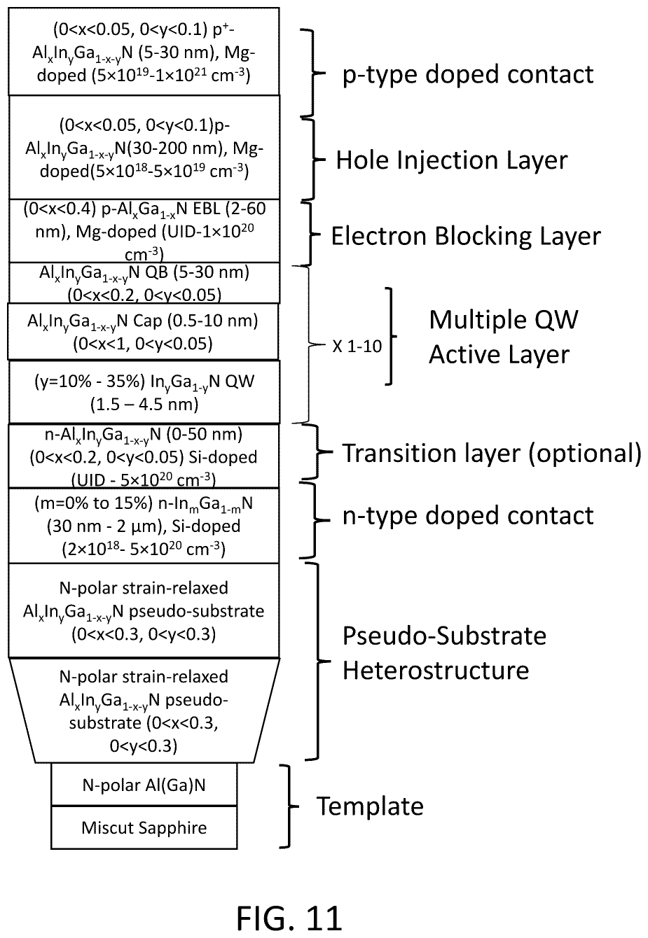

One example of LED is shown in FIG. 11. The group III-nitrides shown in the figure and the layer thicknesses are for illustrative purposes only. Other group III-nitrides and layer thicknesses can be used. The LED includes a template, such as N-polar GaN on miscut sapphire, on which a pseudo-substrate heterostructure of a type described herein is fabricated. An n-type doped group III-nitride is grown on L_{B2} of the pseudo substrate and serves as a n-contact. A light-emitting active layer comprising multiple quantum wells (QWs) is fabricated over the n-contact and an electron blocking layer and hole injection layer are grown on the active layer. Finally, a p-type doped group III-nitride p-contact is formed on the hole injection layer.

### Example

This Example demonstrates the in situ multi-step porosification of a pseudo-substrate that includes an initial InGaN/InGaN/GaN SL (SL_{A}) on an N-polar GaN template. This in situ multi-step porosification technique produces a highly strain-relaxed pseudo-substrate SL_{B2} without degrading the material's crystalline quality.

### Experimental Methods

A 58 nm thick N-polar InᵥGa₁₋ᵥN/InᵥGa₁₋ᵥN/GaN SL (SL_{A}) layer (structure S₀) was deposited on the GaN template on a sapphire substrate with a 4° miscut towards the a-plane using the MOCVD technique. Each period of the SL_{A} consisted of 2.7 nm-thick InᵥGa₁₋ᵥN (v=0.152) stratum, a 7 nm-thick In_{w}Ga_{1-w}N (w=0.084) stratum, and 1-2 nm-thick sublayer of GaN. SL_{A} has 5 periods. The MOCVD reactor temperature and pressure were maintained at 820° C. and 666 mbar during growth. The deposition of the InGaN sublayers in the SL_{A} was performed using trimethylindium (TMIn), triethylgallium (TEGa), and ammonia (NH₃) precursors in the presence of N₂ carrier gas. A mixture of N₂/H₂ carrier gas was used for the deposition of the thin GaN sublayers in the SL_{A}. While the TMIn/TEGa ratio was set to 2.5 along with 268 mmol/min of NH₃, the variation of the indium composition in the InᵥGa₁₋ᵥN and In_{w}Ga_{1-w}N strata of SL_{A} resulted from the introduction of H₂ and N₂ carrier gas during epitaxial growth. After that, the reactor temperature was increased to 1020° C. for the in situ thermal porosification of the N-polar SL_{A} via thermal decomposition. The porosification was performed for 8-10 mins under N₂ gas ambient. Next, a 35 nm-thick GaN layer (structure S₁) was deposited on top of the porosified InGaN/InGaN/GaN SL to form a first coalescence layer. TEGa and NH₃ were used as the precursors, with flow rates of 24 mol/min and 133 mmol/min, respectively, at 1020° C. and 134 mbar pressure.

Next, an intermediate InₓGa₁₋ₓN (2.8 nm)/In_{y}Ga_{1-y}N (5.2 nm)/GaN (<1 nm) superlattice (SL_{B1}) with x=0.13 and y=0.09, a total of ten periods, and a total thickness of 80 nm (structure S₂) was deposited on top of the first GaN coalescence layer using a TMIn/TEGa ratio of 2.5 and a NH₃ flowrate of 268 mmol/min at 850° C. and 666 mbar pressure. A small amount of H₂ carrier gas was introduced during the growth of the thin GaN sublayers (<1 nm) of the SL_{B1} to improve the surface morphology of the structure, which resulted in the stratification of each InGaN sublayer of SL_{B1} into a In_{y}Ga_{1-y}N stratum over a InₓGa₁₋ₓN stratum. In situ thermal porosification of SL_{B1} was carried out, followed by GaN coalescence layer deposition (structure S₃), using the same process parameters as mentioned above.

Finally, an upper (terminal) 160 nm-thick InₓGa₁₋ₓN (2.8 nm)/In_{y}Ga_{1-y}N (5.2 nm)/GaN (<1 nm) superlattice (SL_{B2}) having 20 periods was deposited on top of structure S₃ to obtain a partially relaxed pseudo-substrate (structure S₄). The SL_{B2} was deposited on top of the S₃ without taking S₃ out of the reactor to avoid any surface contamination. A comparative pseudo-substrate heterostructure, S₅ in FIG. 1, was prepared with a single porosification step as a comparative sample which was coloaded into the reactor with structure S₄. Comparative structure S₅ differed from pseudo-substrate S₄ in that SL_{A} was omitted.

After the deposition, the composition and relaxation of the heterostructure samples were measured using the reciprocal space mapping (RSM) technique and omega-2theta scans in the high-resolution X-ray diffraction (XRD) Panalytical Empyrean tool. The surface morphology was evaluated using a Zeiss Gemini 300 scanning electron microscopy (SEM) at 3 KV and Bruker Icon atomic force microscopy (AFM). A cross-sectional SEM scan at 5 KV was performed to identify the in-situ porous layers. Photoluminescence (PL) measurements were also performed using a HORIBA LabRAM HR Evolution Raman spectroscopy tool with a 405 nm LASER at 5% LASER power and with a spot size of 300 μm. The PL measurement helped to evaluate the shift of the emission wavelength with increased relaxation in the N-polar InGaN pseudo-substrate.

### Results and Discussion

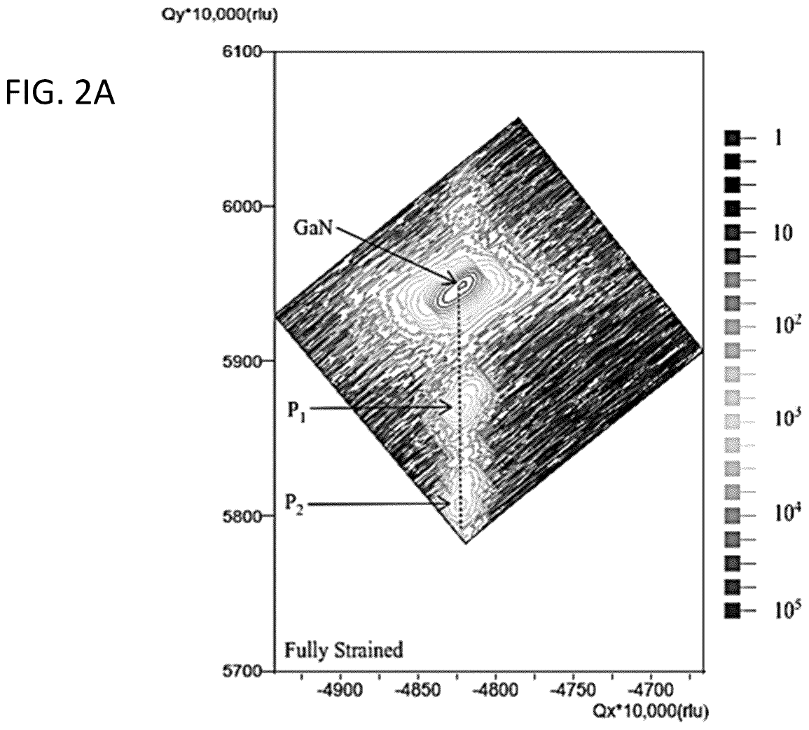

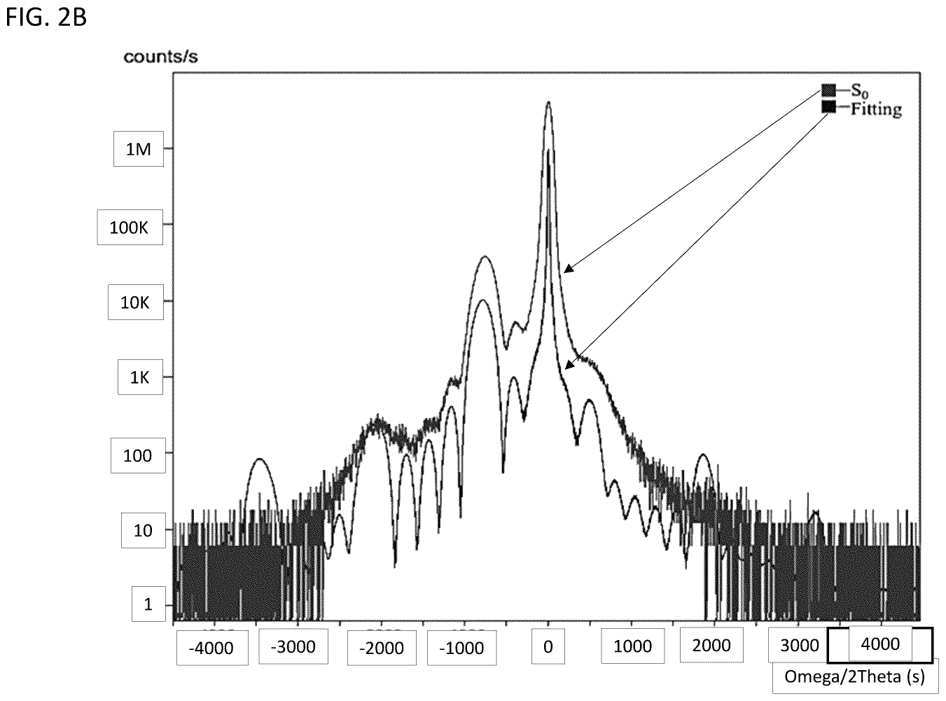

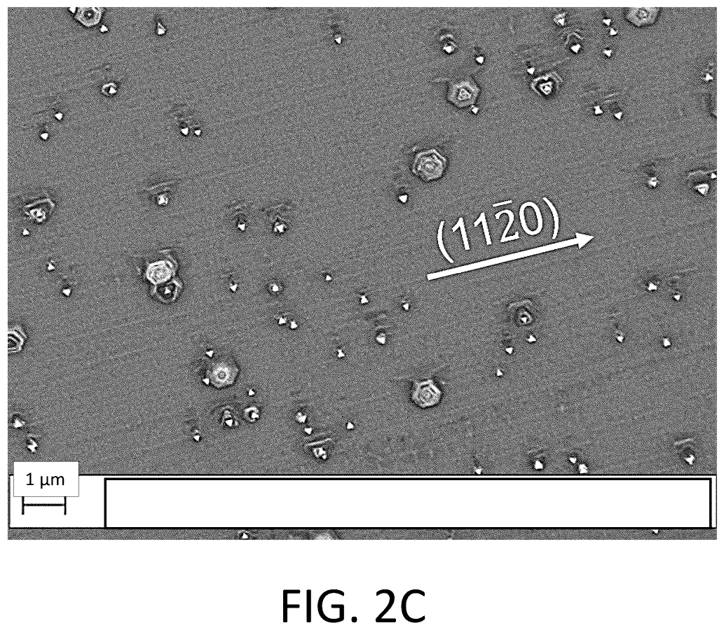

First, the composition and the growth rate of the SL_{A} sublayers were measured using RSM across the GaN (1̅1̅24) reflection (FIG. 2A) and an omega-2theta scan across the GaN (0002) reflection (FIG. 2B). The peaks in the RSM of the S₀ sample taken across the (1̅1̅24) GaN reflection showed almost fully strained InGaN with an indium composition of a=15.2% and b=8.4% (FIG. 2A). From FIG. 2A, it was observed that there were two indium peaks below the GaN peak. The first peak (P₁) provided a composition of 8.4% indium and the second peak (P₂) gave a composition of 15.2% indium in the InGaN. Although the TEGa and TMIn flow rate was not changed, the indium composition in the upper stratum of the InGaN alloy was reduced due to the introduction of H₂ carrier gas during the deposition of the thin GaN sublayers above the InGaN sublayers in SL_{A}. The H₂ improved the morphology of the epitaxial layers by improving the diffusion length of the group-III adatoms, but it also caused the desorption of indium; although the indium composition was reduced, the hillock density on the surface of the N-polar InGaN epitaxial layers was also reduced by the H₂ acting as a surfactant. The omega-2theta plot showed very low intensity of the thickness fringes and higher order SL peaks in FIG. 2B. This decrease in the intensity of the SL peaks and thickness fringes was related to the 4° misorientation of the sapphire substrate causing increased surface or interface roughness. The SEM image showed some hexagonal and triangular hillock formation due to the increased lattice mismatch between the N-polar InGaN and GaN sublayers (FIG. 2C). The different types of hillock formation are related to the anisotropic step propagation velocity of the group-III adatoms towards the a-plane and m-plane of the N-polar GaN. The GaN (112̅0) plane is pointed out in the SEM image (FIG. 2C).

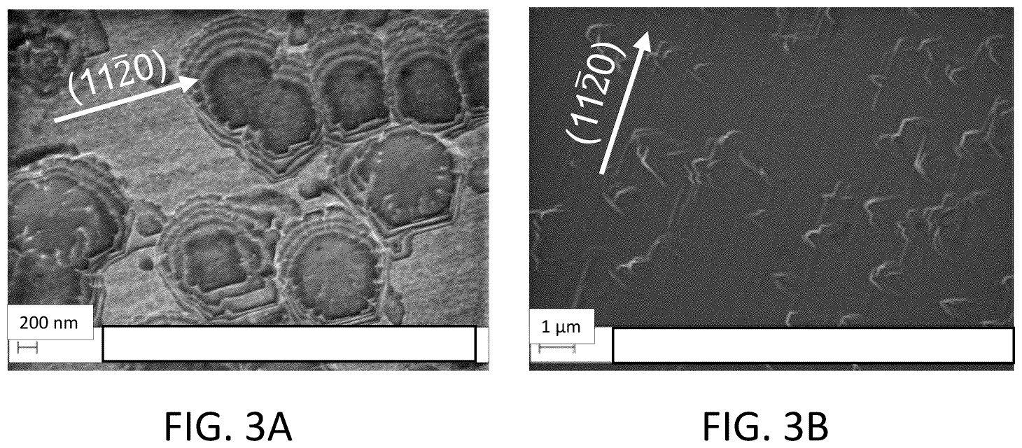

The surface of the thermally decomposed (“porosified”) sample S₀ showed some holes with a depth of around 40-60 nm (FIG. 3A). The average hole diameter was determined to be around 1.4 μm. The depth and diameters of the holes were measured using AFM. The deposition of the GaN coalescence layer partially filled the holes and retrieved the miscut steps (FIG. 3B), which contributes to a smooth morphology in N-polar III-nitride films. The miscut steps facilitate step-flow deposition mode in N-polar III-nitride epitaxial layers deposited using the MOCVD technique. Without the miscut steps, the N-polar films showed hexagonal hillocks with a high dislocation density. The hillocks and the dislocation densities decreased with increasing misorientation angle of the substrate.

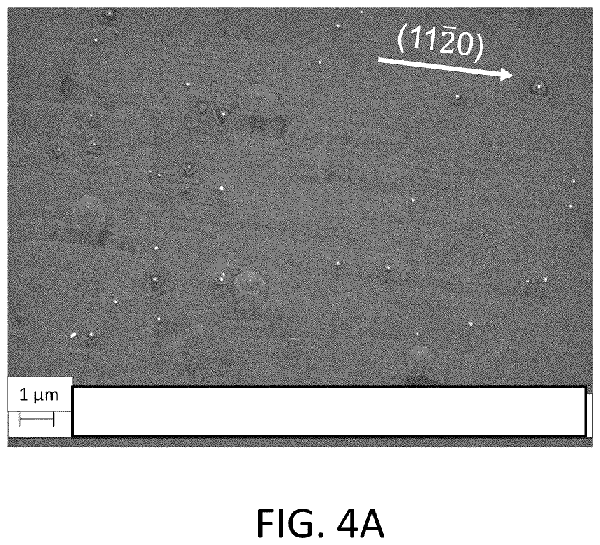

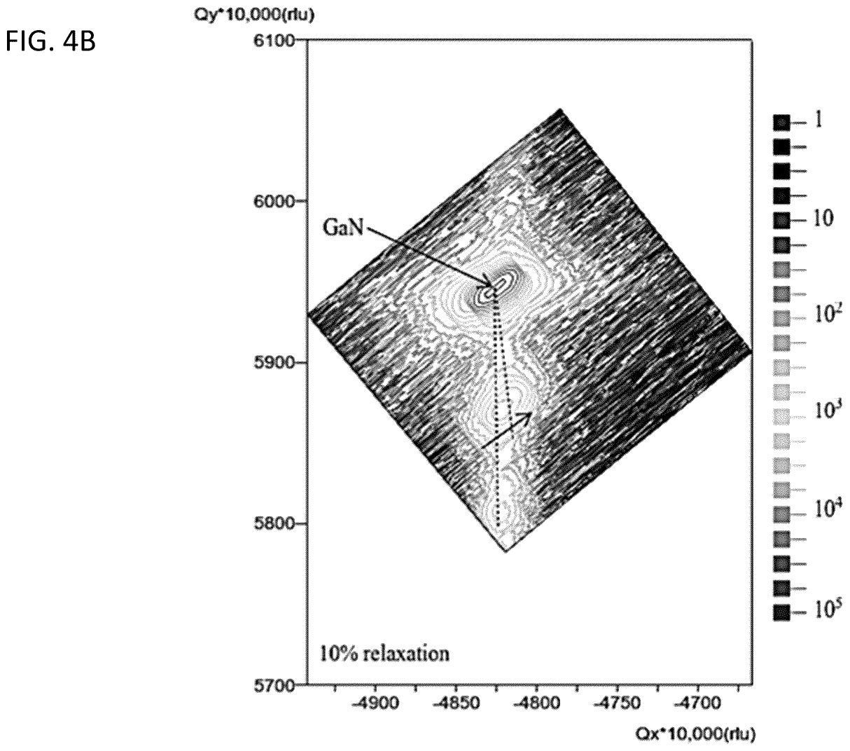

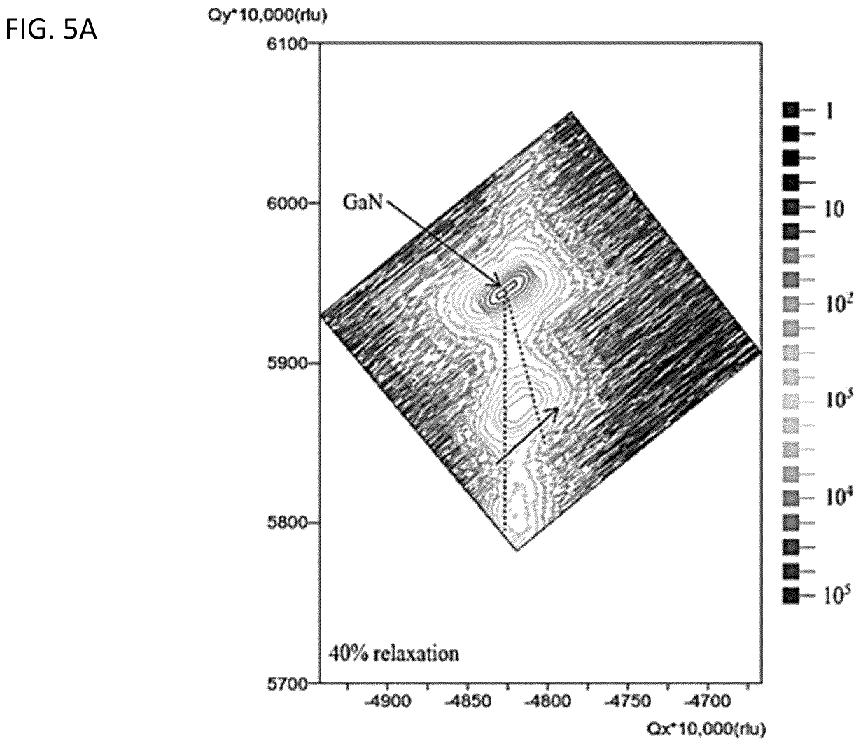

The sample S₂ (hillock density=2.6×10⁷/cm²) with the SL_{B1} layer showed ˜1.6 times reduced hillock density compared to the sample S₀ (hillock density 4.2×10⁷/cm²) indicating that the in situ porosification and coalescence layer deposition assisted reduction of hillock densities (FIG. 4A). Interestingly, hillock size and density have been reported to increase with increased InGaN thickness; this Example shows an opposite trend. (Keller, Stacia, et al., 2014.) This behavior might be related to the epitaxial overgrowth of the GaN or InGaN sublayers on top of the porous InGaN sublayers which helped to reduce the hillock density by reducing threading dislocation density. The SL_{B1} layer only attained a maximum relaxation of 10%, as illustrated in FIG. 4B. The sample S₂ did not relax extensively, likely attributed to the lower overall thickness (80 nm) of SL_{B1}, limiting the driving force for strain relaxation, and relatively low porosity of the SL_{A} layer.

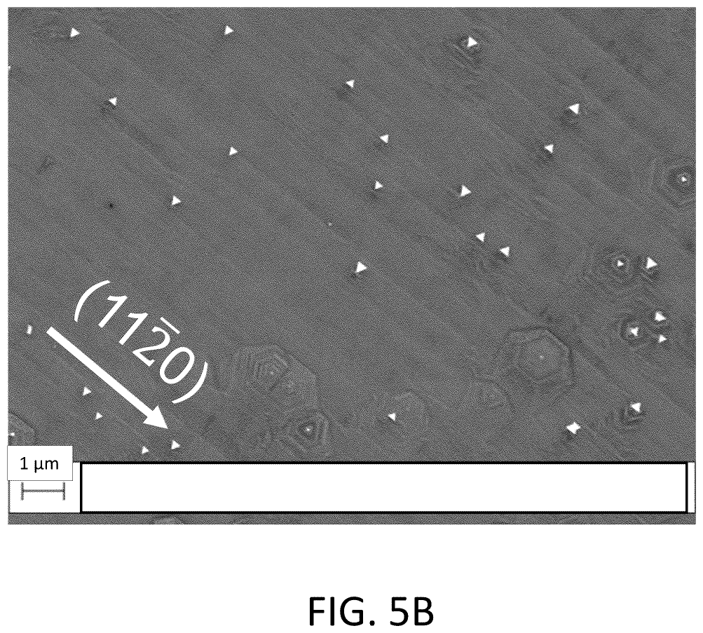

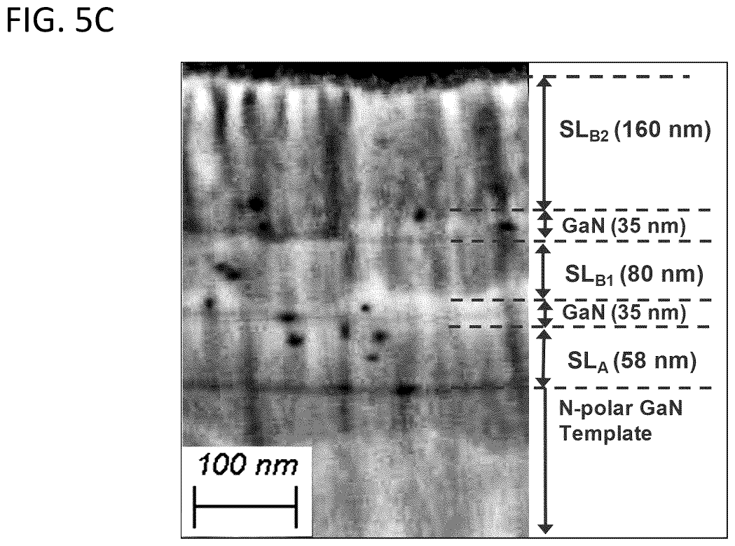

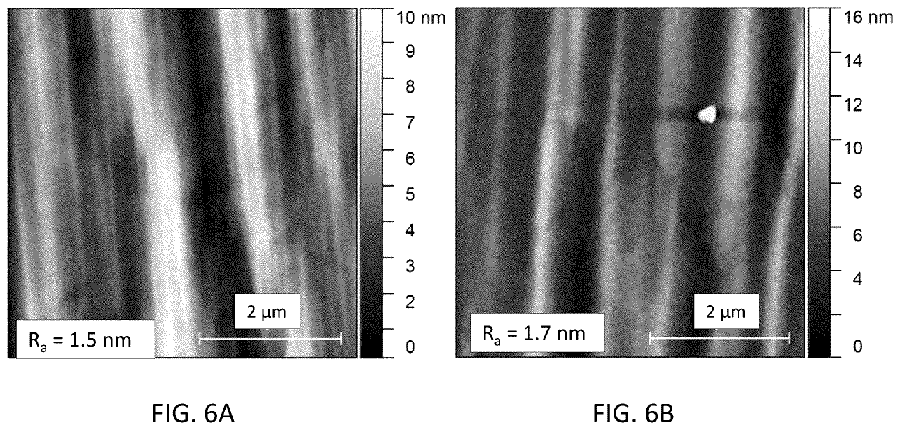

In the formation of structure S₃, it was expected that some of the previously deposited SL_{B1} sublayers would get porosified and increase the relaxation of the subsequently grown InGaN layers. On top of structure S₃, SL_{B2} in structure S₄ showed a 23% lower density of hillocks compared to structure S₂ (FIG. 5B) along with a 40% bulk strain relaxation (FIG. 5A). The InGaN high-intensity peak intensity can be observed to be stretching from fully strained to 40% relaxed, without the presence of a local maxima within the peak. The stretching of the peak intensity of the InGaN indicated that there was a gradual change in the relaxation of SL_{B2} throughout the epitaxial layers. The peak intensity of SL_{B2} merged with the rest of the InGaN layers (in SL_{B1} and SL_{A}), causing an extended and oval-shaped peak in the RSM. The multi-step porosification along with the increasing thickness of the InGaN layer enhanced the average relaxation in the SL_{B2} layer in sample S₄. The cross-sectional SEM image of S₄ showed evidence of the multi-step porosification process (FIG. 5C). The porous layers can be identified with a few microscopic voids that could not be coalesced and can be observed in the cross-sectional SEM scans as shown in FIG. 5C. The SL_{A} superlattice showed higher porosity compared to the SL_{B1} superlattice due to the higher indium content and lower thermal stability of the InᵥGa₁₋ᵥN (v=0.152) in SL_{A} compared to the InₓGa₁₋ₓN (x=0.13) in SL_{B1}.

Some pores were also observed at the sidewalls of the GaN coalescence layer, which may be due to some of the larger pores requiring >35 nm of GaN for efficient planarization. Such pores would not be effectively filled, leaving unfilled voids.

The AFM scans (taken over a surface area of 5 μm×5 μm) of S₀ and S₄ taken between hillocks showed that the surface roughness had not increased with the multi-step in situ porosification and the RMS roughness was below 2 nm, indicating a good surface morphology.

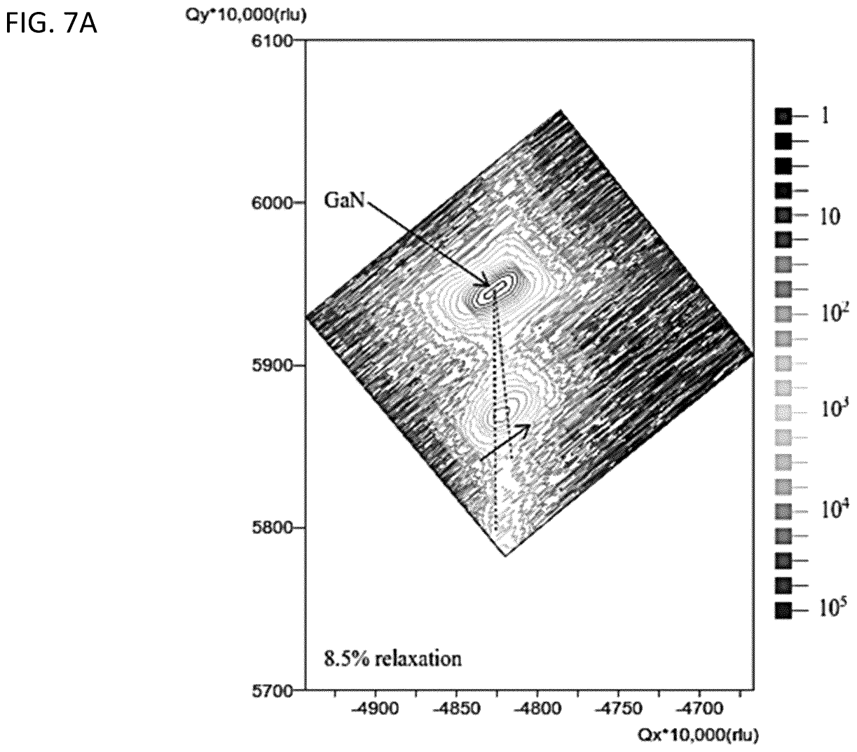

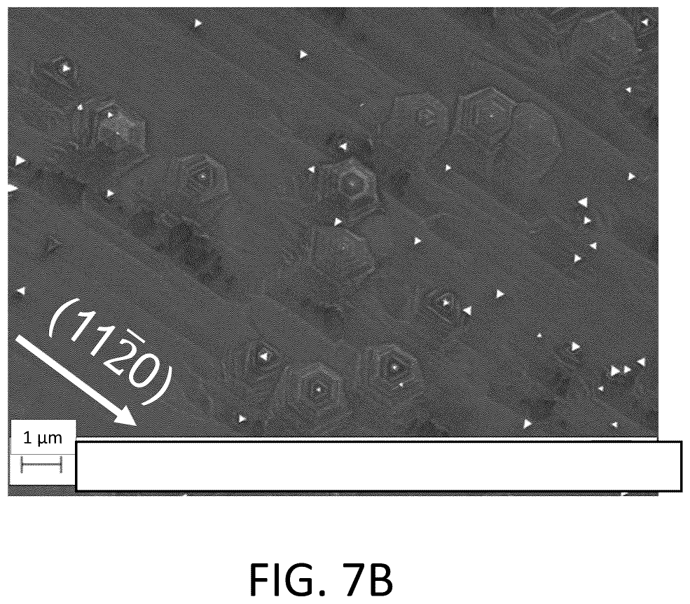

Finally, the comparative pseudo-substrate structure S₅, which lacked the initial SL_{A} layer, showed 8.5% strain relaxation (FIG. 7A) with a morphology (FIG. 7B) similar to that of structure S₄. The hillock density of S₅ (2.4×10⁷/cm²) was 16% higher than S₄ (2×10⁷/cm²), indicating a higher threading dislocation density in the S₅ sample. Measuring the threading dislocation density using the XRD rocking curve analysis becomes non-trivial in N-polar InGaN films because of the diverse facets present in the surface hillocks. Instead, since hillock formation is closely tied to the threading dislocation density, any alteration in hillock density serves as a distinct indicator of changes in the dislocation density. In the sample S₄, SL_{A} and SL_{B1} layers underwent porosification and epitaxial lateral overgrowth, whereas, in S₅, only the SL_{B1} experienced similar processes. The porosification of multiple superlattice structures embedded in the sample and epitaxial overgrowth process helped to achieve an enhanced relaxation and lower hillock density in S₄. The relaxation of S₅ was 31.5% lower compared to the relaxation percentage of S₄. The absence of the SL_{A} layer and a lower number of porosification steps in S₅ significantly decreased the overall relaxation compared to S₄. The gradual relaxation process in S₄ was assisted and enhanced by the initial in situ porosified SL_{A} structure. The two-stage porosification process enabled a higher percentage of porosification without sacrificing the material quality or increasing the surface roughness. The lowering of the thermal stability with an increase in indium content in the SL_{A} InGaN sublayers compared to SL_{B1} & SL_{B2} InGaN sublayers allowed for a higher porosity in SL_{A} layers upon decomposition.

The multi-step porosification process allows for gradual relaxation of the InGaN sublayers where the initial InGaN sublayers are almost fully strained with lower peak intensity and the partially relaxed top layers with a higher and broadened-out peak intensity in RSM scans. Therefore, the relaxation and composition obtained from the RSM scan project an average estimate of the indium composition and relaxation in the bulk film. However, PL measurement using near UV (405 nm) LASER can be used to analyze the surface and near-surface thin film characteristics (<100 nm). Therefore, the PL measurement indicate the relaxation of the InGaN films in the vicinity of the surface. The expected PL spectra near the surface would be mainly dominated by the SL_{B2}. Due to the periodic repetition of the thin 13% InGaN stratum overshadowing that 15.2% InGaN peak. The difference in the intensities was primarily related to the volumetric ratios of the SL_{B2} and SL_{A} layers.

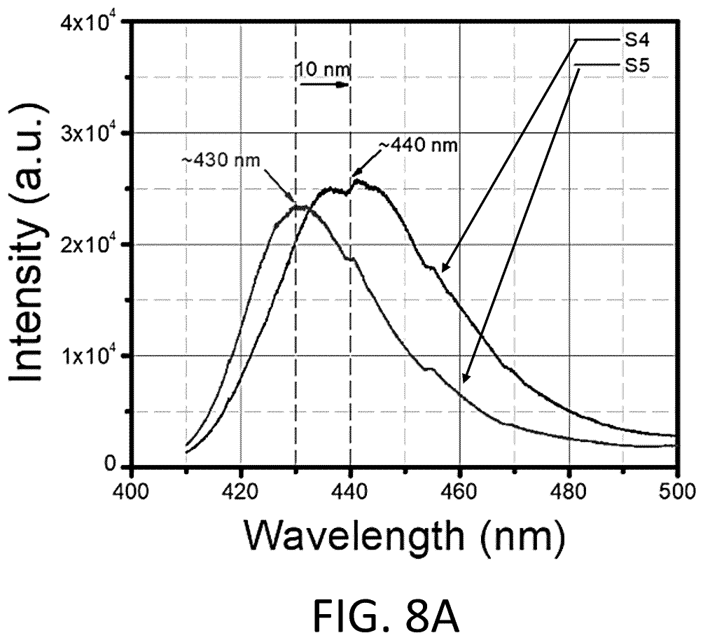

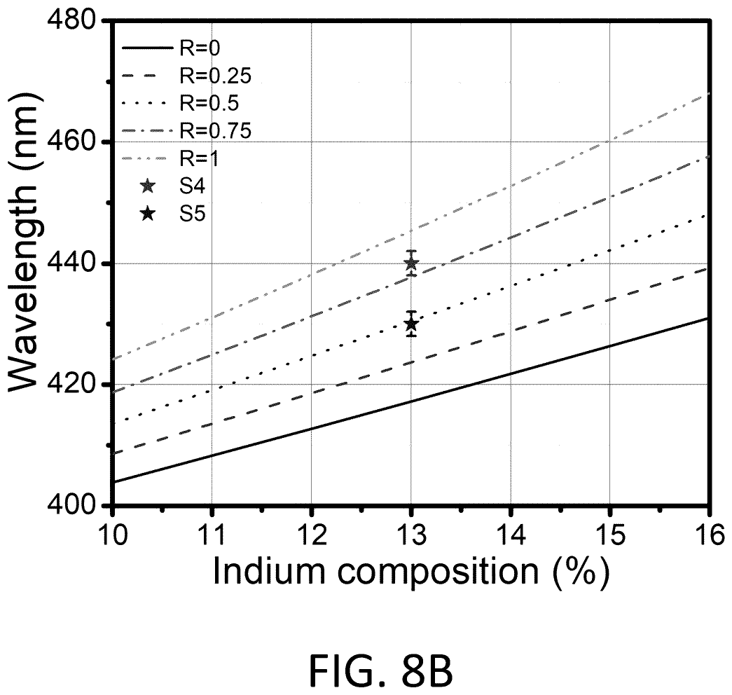

The peak intensity of the PL spectra of the S₄ sample showed a 10 nm redshift compared to the S₅ sample, indicating a reduction of the effective bandgap of the SL_{B2} layer (FIG. 8A). The reduction of the bandgap is related to the change of the lattice constant in the strain-relaxed SL_{B2} sublayers. However, the S₄ and S₅ samples had similar average indium compositions, as measured using the RSM and omega-2theta measurements. So, the reduction of the effective bandgap was related to the relaxation of the SL_{B2}. The relation between the PL peak wavelength, indium composition, and relaxation was obtained using the method discussed by Abdelhamid et al. (Abdelhamid, Mostafa, et al., Journal of Crystal Growth 520 (Aug. 15, 2019): 18-26.) FIG. 8B shows that the SL_{B2} in the S₄ structure was ˜80% relaxed and in the S₅ structure was ˜50% relaxed. The difference in the relaxation between S₄ and S₅ was 30%, which was very similar to the obtained data from the RSM. The data obtained from PL analysis indicated a pronounced relaxation in the uppermost sublayers of the SL_{B2} in the S₄ structure. The S₄ structure has a full-width half-max (FWHM) of 39 nm in the PL spectrum, which was higher than the FWHM for S₅(FWHM=29 nm) observed in FIG. 8A. The higher FWHM of the PL spectra of S₄ was related to the 30% higher relaxation, which was obtained at multiple steps. (Tsai, Wen-Che, et al., Optics Express 22, no. S₂ (Mar. 10, 2014): A416.) The variation in the relaxation in the multi-step porosification process increased the FWHM of the PL spectrum.

Although the PL measurement showed >50% relaxation for both S₄ and S₅, the actual relaxation in the bulk would be much lower. The bulk layers had an average relaxation of SL_{A}, SL_{B1}, and SL_{B2} layers, which was less than the relaxation obtained from the PL spectrum. Thus, for measuring the bulk relaxation, the data obtained from RSM measurement will be considered.

The effect of the relaxation of the InGaN on the lattice constant is shown in Table 1 following the relation given by Pasayat et al. (Pasayat, Shubhra S., et al., Applied Physics Letters 116, no. 11 (Mar. 16, 2020): 111101.) The average indium composition in the InGaN SL is calculated using:

$${In}_{avg} {Ga}_{1 - avg} N = ( {In}_{m} {Ga}_{1 - m} N \times \frac{{t}_{1}}{{t}_{1} + {t}_{2}} ) + ( {In}_{n} {Ga}_{1 - n} N \times \frac{{t}_{2}}{{t}_{1} + {t}_{2}} )$$

where t₁ and t₂ are the corresponding thicknesses of the InₘGa₁₋ₘN and InₙGa₁₋ₙN, respectively. (Ando, Yuto, et al., Journal of Crystal Growth 607 (Apr. 1, 2023): 127100.) The increase in lattice constant from 3.1893 (S₀) to 3.204 (S₄) (Table 1) will help to reduce the electron effective mass and enhance the carrier drift velocity in the channel of HEMTs.

TABLE 1
Summary of the N-polar InGaN samples'
composition, thickness, and relaxation.

| | Average | | | Corresponding | Lattice |
|---|---|---|---|---|---|
| | Indium | Total InGaN | Relax- | composition of | constant |
| Sample | composition | Thickness | ation | fully relaxed | “a” |
| No. | (%) | (nm) | (%) | InGaN (%) | (Å) |
| S₀ | 10.3 | ~48 | 0 | ~0 | 3.1893 |
| S₂ | 10.4 | ~128 | 10 | 1 | 3.1927 |
| S₄ | 10.4 | ~288 | 40 | 4.2 | 3.2040 |
| S₅ | 10.4 | 240 | 8.5 | 0.89 | 3.1924 |

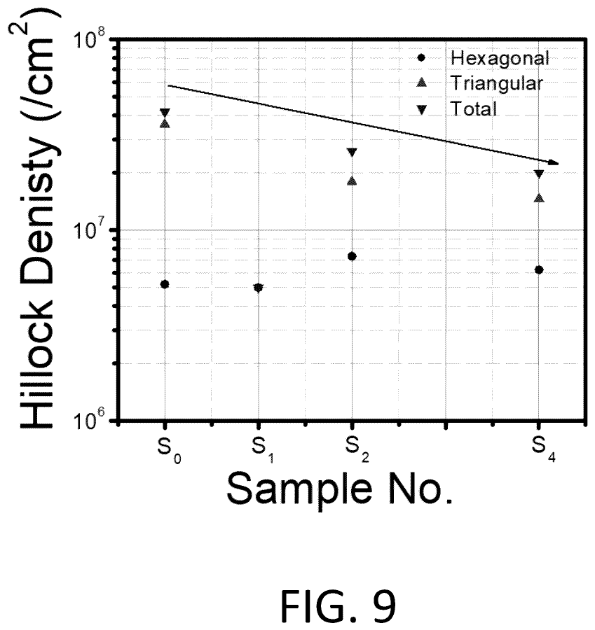

The variation of the hillock density was examined for the structures S₀, S₁, S₂, and S₄. The total hillock density was reduced from 4×10⁷/cm² to 2×10⁷/cm² (FIG. 9) from sample S₀ to sample S₄, which indicates that in situ porosification helped to improve the crystalline quality.

Increasing the number of porosification steps in the MOCVD growth can further increase the strain relaxation percentage in the pseudo-substrate. This technique not only gives the flexibility of precisely controlling the relaxation percentage but also allows for the use of different indium compositions in different layers of the pseudo-substrate heterostructure, which is helpful in terms of controlling hillock density and surface morphology.

### CONCLUSION

The multi-step in situ porosification can be used for acquiring a partially relaxed N-polar InGaN pseudo-substrate with a lower hillock density. Moreover, the multi-step in situ porosification technique can be repeated multiple times to deposit a thicker and higher composition (>10%) InGaN layers with enhanced relaxation without degrading the crystal morphology. This Example demonstrates that the large area porosification of an N-polar InGaN sample can be achieved by readily porosifying it without the use of a GaN cap layer, which is suitable for N-polar III-nitride materials. The use of a GaN coalescence layer helps to achieve a smooth surface morphology and reduced hillock density, which is helpful for the deposition of the high-quality epitaxial layers on top of the pseudo-substrate, which is useful for electronic or opto-electronic devices. A 40% bulk InGaN relaxation was achieved by two-step porosification of the N-polar InGaN epitaxial layers of a total thickness>240 nm, surface roughness<2 nm, and 50% reduction of total hillock density. The enhanced adaptability of the multi-step in situ porosification method is well-suited for managing the degree of relaxation and the composition of the N-polar InGaN layers. This flexible control of the relaxation contributes to the precise adjustment of the lattice constant, influencing both the electron mobility and the saturation velocity of the channel layer in HEMTs.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A pseudo-substrate comprising:
a template;
a pseudo-substrate heterostructure on the template, the pseudo-substrate heterostructure comprising:
a first porosified layer comprising a metal nitride alloy on a template;
a first coalescence layer comprising a metal nitride alloy on the first porosified layer;
optionally, one or more additional structures on the first coalescence layer, wherein each of the one or more additional structures comprises an additional porosified layer comprising a metal nitride alloy; and an additional coalescence layer comprising a metal nitride alloy on the additional porosified layer; and
an upper, non-porosified, at-least-partially strain-relaxed layer comprising a metal nitride alloy on the first coalescence layer or on a terminal additional coalescence layer.

2. The pseudo-substrate of claim 1, wherein the metal nitride alloy of the first porosified layer, the metal nitride alloy of the one or more additional porosified layers, if present, and the metal nitride alloy of the upper, non-porosified, at least-partially strain relaxed layer are (Al,In)GaN alloys.

3. The pseudo-substrate of claim 2, wherein the first coalescence layer and the one or more additional coalescence layers, if present, comprise a metal nitride selected from GaN, AlN, an AlInGaN alloy, an AlInN alloy, an AlBN alloy, a GaBN alloy, and an AlScN alloy.

4. The pseudo-substrate of claim 2, wherein the template comprises of GaN or group III-nitride layers on native GaN, native AlN, SiC, or silicon substrate.

5. The pseudo-substrate of claim 1, wherein at least one of the first porosified layer, the one or more additional porosified layers, if present, and the upper, non-porosified, at least-partially strain relaxed layer is a superlattice.

6. The pseudo-substrate of claim 1, wherein at least one of the first porosified layer, the one or more additional porosified layers, if present, and the upper, non-porosified, at least-partially strain relaxed layer consists of a single layer of metal nitride alloy.

7. The pseudo-substrate of claim 1, comprising at least one of the additional structures on the first coalescence layer.

8. The pseudo-substrate of claim 7, wherein the metal nitride alloy of the first porosified layer, the at least one additional porosified layer, and the upper, non-porosified, at least-partially strain relaxed layer is an InGaN alloy, and the metal nitride of the first coalescence layer and the at least one additional coalescence layer is GaN.

9. The pseudo-substrate of claim 8, wherein the first porosified layer, the at least one additional porosified layer, and the upper, non-porosified, at least-partially strain relaxed layer are superlattices.

10. An electronic or optoelectronic device comprising one or more epitaxial active layers on a pseudo-substrate, the pseudo-substrate comprising:
a template;
a pseudo-substrate heterostructure on the template, the pseudo-substrate heterostructure comprising:
a first porosified layer comprising a metal nitride alloy on a template;
a first coalescence layer comprising a metal nitride alloy on the first porosified layer;
optionally, one or more additional structures on the first coalescence layer, wherein each of the one or more additional structures comprises an additional porosified layer comprising a metal nitride alloy; and an additional coalescence layer comprising a metal nitride alloy on the additional porosified layer; and
an upper, non-porosified, at-least-partially strain-relaxed layer comprising a metal nitride alloy on the first coalescence layer or on a terminal additional coalescence layer.

11. The electronic or optoelectronic device of claim 10, wherein the electronic or optoelectronic device is a high electron mobility transistor, a light-emitting diode, or a laser diode.

12. A method of making a pseudo-substrate, the method comprising:
forming a first layer comprising a metal nitride alloy on a template using epitaxial growth;
porosifying the metal nitride alloy of the first layer via a thermal decomposition of the metal nitride alloy to form a first porosified layer;
forming a first coalescence layer comprising a metal nitride alloy on the first porosified layer via epitaxial growth;
optionally, forming one or more additional structures on the first coalescence layer, wherein each of the one or more additional structures are made by: forming an additional layer comprising a metal nitride alloy and porosifying the additional layer via a thermal decomposition of the metal nitride alloy to form an additional porosified layer; and forming an additional coalescence layer comprising a metal nitride alloy on the additional porosified layer via epitaxial growth; and
forming an upper, non-porosified, at-least-partially strain-relaxed layer comprising a metal nitride alloy on the first coalescence layer or on a terminal additional coalescence layer.

13. The method of claim 12, wherein the metal nitride alloy of the first porosified layer, the metal nitride alloy of the one or more additional porosified layers, if present, and the metal nitride alloy of the upper, non-porosified, at least-partially strain relaxed layer are (Al,In)GaN alloys.

14. The method of claim 13, wherein the first coalescence layer and the one or more additional coalescence layers, if present, comprise a metal nitride selected from GaN, AlN, an AlInGaN alloy, an AlInN alloy, an AlBN alloy, a GaBN alloy, and an AlScN alloy.

15. The method of claim 13, wherein the template comprises of GaN or group III-nitride layers on native GaN, native AlN, SiC, or silicon substrate.

16. The method of claim 13, wherein at least one of the first porosified layer, the one or more additional porosified layers, if present, and the upper, non-porosified, at least-partially strain relaxed layer is a superlattice.

17. The method of claim 13, wherein at least one of the first porosified layer, the one or more additional porosified layers, if present, and the upper, non-porosified, at least-partially strain relaxed layer consists of a single layer of metal nitride alloy.

18. The method of claim 12, wherein at least one of the additional structures is formed on the first coalescence layer.

19. The method of claim 18, wherein the metal nitride alloy of the first porosified layer, the at least one additional porosified layer, and the upper, non-porosified, at least-partially strain relaxed layer is an InGaN alloy, and the metal nitride alloy of the first coalescence layer and the at least one additional coalescence layer is GaN.

20. The method of claim 19, wherein each of the first porosified layer, the at least one additional porosified layer, and the upper, non-porosified, at least-partially strain relaxed layer are superlattices.
